(19) United States
(12) Patent Application Publication
(10) Pub. No.: US 2013/0244396 A1
(43) Pub. Date: Sep. 19, 2013

(54) FIELD EFFECT TRANSISTORS HAVING AN EPITAXIAL LAYER ON A FIN AND METHODS OF FABRICATING THE SAME

(71) Applicant: SAMSUNG ELECTRONICS CO., LTD., Suwon-si (KR)

(72) Inventors: Chang-Woo OH, Suwon-si (KR); Sang-Hoon Lee, Seongnam-si (KR); Sung-Bong Kim, Suwon-si (KR); Hyung-Suk Lee, Suwon-si (KR)

(73) Assignee: Samsung Electronics Co., Ltd., Suwon-si (KR)

(21) Appl. No.: 13/684,667

(22) Filed: Nov. 26, 2012

(30) Foreign Application Priority Data
Mar. 19, 2012 (KR) 10-2012-0027737

(51) Int. Cl. H01L 29/66

(52) U.S. Cl. CPC H01L 29/66795
USPC 438/400

(57) ABSTRACT

A method of fabricating a fin field effect transistor may include forming a fin portion protruding from a substrate, forming a device isolation layer to cover a lower sidewall of the fin portion, forming a semiconductor layer using an epitaxial method to cover an upper sidewall and a top surface of the fin portion, selectively etching an upper portion of the device isolation layer to form a gap region between a top surface of the device isolation layer and a bottom surface of the semiconductor layer, and forming a gate electrode pattern on the semiconductor layer to fill the gap region. Related devices are also described.

### CROSS-REFERENCE TO RELATED APPLICATION

This application claims priority to Korean Patent Application No. 10-2012-0027737, filed on Mar. 19, 2012 in the Korean Intellectual Property Office, the disclosure of which is hereby incorporated herein in its entirety by reference.

### BACKGROUND

Embodiments of the inventive concepts relate to field effect transistors, and in particular, to fin field effect transistors and methods of fabricating the same.

Semiconductor integrated circuit devices are increasingly being used in consumer, commercial and other electronic devices. The semiconductor devices can include a memory device for storing data, a logic device for processing data, and a hybrid device including both of memory and logic elements. Due to the increased demand for electronic devices with fast speed and/or low power consumption, the semiconductor devices should provide a fast operating speed and/or a low operating voltage. To satisfy these technical requirements, the complexity and/or increased integration density of semiconductor devices may increase.

### SUMMARY

Embodiments of the inventive concepts provide methods of fabricating a fin field effect transistor, which can reduce or suppress short channel effects from occurring.

According to example embodiments of the inventive concepts, a method of fabricating a field effect transistor may include forming a fin portion protruding from a substrate, forming a device isolation layer on, and in some embodiments to cover, a lower sidewall of the fin portion, forming a semiconductor layer using an epitaxial method on, and in some embodiments to cover, an upper sidewall and a top surface of the fin portion, selectively etching an upper portion of the device isolation layer to form a gap region between a top surface of the device isolation layer and a bottom surface of the semiconductor layer, and forming a gate electrode pattern on the semiconductor layer in, and in some embodiments to fill, the gap region.

In example embodiments, the gap region may be formed to expose a portion of a sidewall of the fin portion between the top surface of the device isolation layer and the bottom surface of the semiconductor layer.

In example embodiments, the semiconductor layer may comprise a material, whose lattice constant and/or bandgap is different from that of the fin portion.

In example embodiments, the semiconductor layer may comprise silicon-germanium (SiGe).

In example embodiments, the semiconductor layer may extend along an extending direction of the fin portion.

In example embodiments, the selectively etching of the upper portion of the device isolation layer may be performed after the forming of the semiconductor layer.

In example embodiments, the method may further include forming a gate dielectric between the gate electrode pattern and the semiconductor layer.

In example embodiments, the method may further include etching the fin portion to have a rounded upper portion thereof prior to forming the semiconductor layer so that the semiconductor layer is formed to have a rounded surface.

According to other example embodiments of the inventive concepts, a method of fabricating a field effect transistor may include forming a fin portion protruding from a substrate, forming a device isolation layer on, and in some embodiments to cover, a lower sidewall of the fin portion, etching an upper portion of the fin portion exposed by the device isolation layer to form a rounded fin portion, growing a semiconductor layer using the rounded fin portion as a seed layer, forming a gate dielectric on the semiconductor layer, and forming a gate electrode pattern on the gate dielectric to cross the fin portion.

In example embodiments, the semiconductor layer may be grown to extend along the rounded fin portion and have a rounded surface.

In example embodiments, the semiconductor layer may be grown such that a gap region may be formed between the rounded surface of the semiconductor layer and the device isolation layer.

In example embodiments, the method may further include after the forming of the semiconductor layer, selectively etching an upper portion of the device isolation layer to expand the gap region between the semiconductor layer and the etched device isolation layer.

In example embodiments, the selectively etching is performed efficiently to expose a portion of a sidewall of the fin portion.

According to still other example embodiments of the inventive concepts, a field effect transistor may include a fin portion protruding from substrate, a device isolation layer on a lower sidewall of the fin portion, a semiconductor layer on, and in some embodiments covering, a top surface and an upper sidewall of the fin portion, a gate electrode pattern on the semiconductor layer to cross the fin portion, and a gate dielectric between the semiconductor layer and the gate electrode pattern. A bottom surface of the semiconductor layer may be spaced apart from a top surface of the device isolation layer, and the gate electrode pattern extends between the bottom surface of the semiconductor layer and the top surface of the device isolation layer.

In example embodiments, the semiconductor layer may include a material whose lattice constant and/or bandgap is different from the fin portion.

In example embodiments, the fin portion includes a rounded upper portion and the semiconductor layer includes a rounded surface.

According to still other embodiments of the inventive concepts, a field effect transistor may include a fin portion protruding from a substrate, the fin portion having a rounded upper portion, a device isolation layer on a lower sidewall of the fin portion, a semiconductor layer on the rounded upper portion of the fin portion, the semiconductor layer having a rounded surface, a gate dielectric on the semiconductor layer, and a gate electrode pattern on the gate dielectric to cross the fin portion.

In example embodiments, the semiconductor layer is an epitaxial semiconductor layer.

In example embodiments, the rounded surface of the semiconductor layer is spaced apart from the device isolation layer such that a gap region is provided between the rounded surface of the semiconductor layer and the device isolation layer.

In example embodiments, the sidewall of the fin portion is exposed in the gap region, the gate dielectric extends on the sidewall of the fin portion that is exposed in the gap region, and the gate electrode pattern extends on the gate dielectric that is on the sidewall of the fin portion that is exposed in the gap region.

### BRIEF DESCRIPTION OF THE DRAWINGS

Example embodiments will be more clearly understood from the following brief description taken in conjunction with the accompanying drawings. FIGS. 1 through 32 represent non-limiting, example embodiments as described herein.

FIGS. 1, 4, 7, 10, and 13 are perspective views illustrating a method of fabricating a field effect transistor according to example embodiments of the inventive concepts.

FIGS. 2, 5, 8, 11, and 14 are sectional views taken along line A-A′ of FIGS. 1, 4, 7, 10, and 13, respectively.

FIGS. 3, 6, 9, 12, and 15 are sectional views taken along line B-B′ of FIGS. 1, 4, 7, 10, and 13, respectively.

FIG. 16 is an enlarged view illustrating a fin portion and a region adjacent thereto of FIG. 14.

FIGS. 17, 20, and 23 are perspective views illustrating a method of fabricating a field effect transistor according to other example embodiments of the inventive concepts.

FIGS. 18, 21, and 24 are sectional views taken along line A-A′ of FIGS. 17, 20, and 23, respectively.

FIGS. 19, 22, and 25 are sectional views taken along line B-B′ of FIGS. 17, 20, and 23, respectively.

FIGS. 26 and 29 are perspective views illustrating a method of fabricating a field effect transistor according to still other example embodiments of the inventive concepts.

FIGS. 27 and 30 are sectional views taken along line A-A′ of FIGS. 26 and 29, respectively.

FIGS. 28 and 31 are sectional views taken along line B-B′ of FIGS. 26 and 29, respectively.

FIG. 32 is a block diagram of an electronic system including a fin field effect transistor according to example embodiments of the inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concepts of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements or layers should be interpreted in a like fashion (e.g., “between” versus “directly between,” “adjacent” versus “directly adjacent,” “on” versus “directly on”). Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

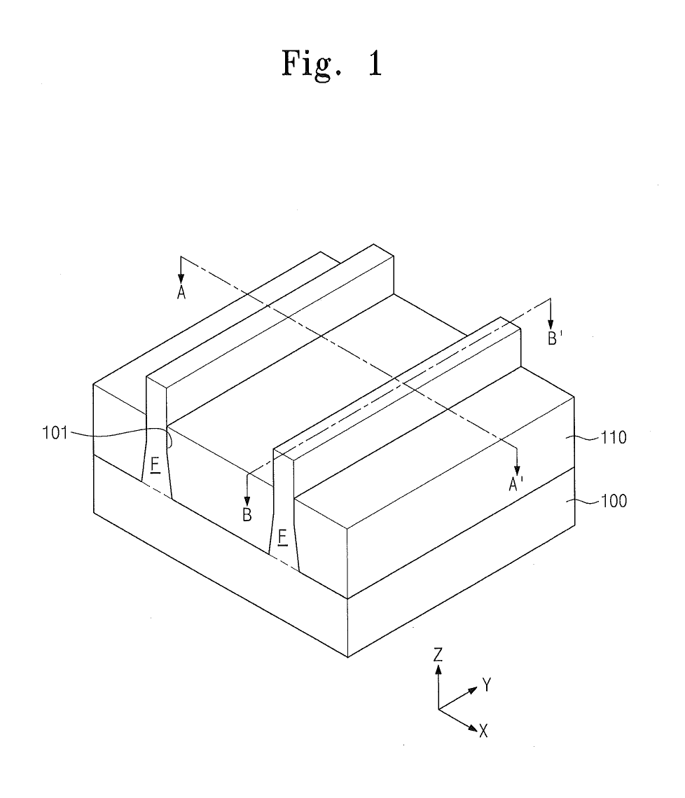

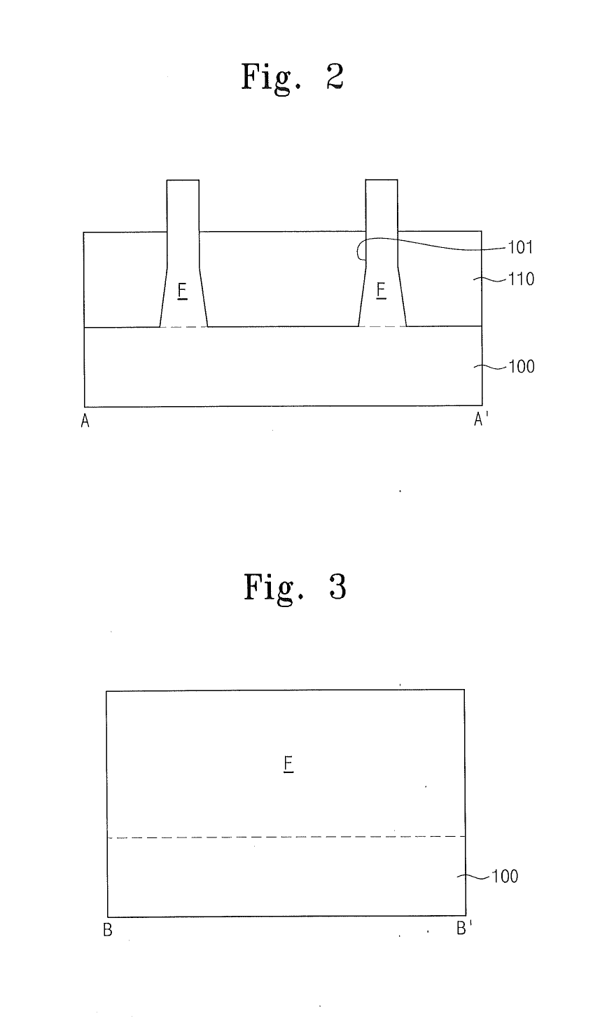

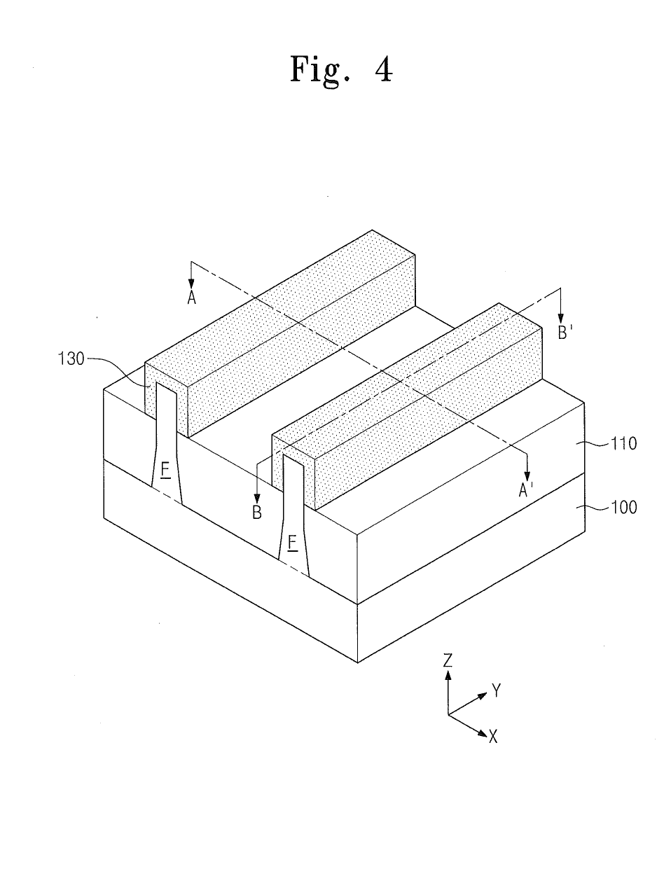

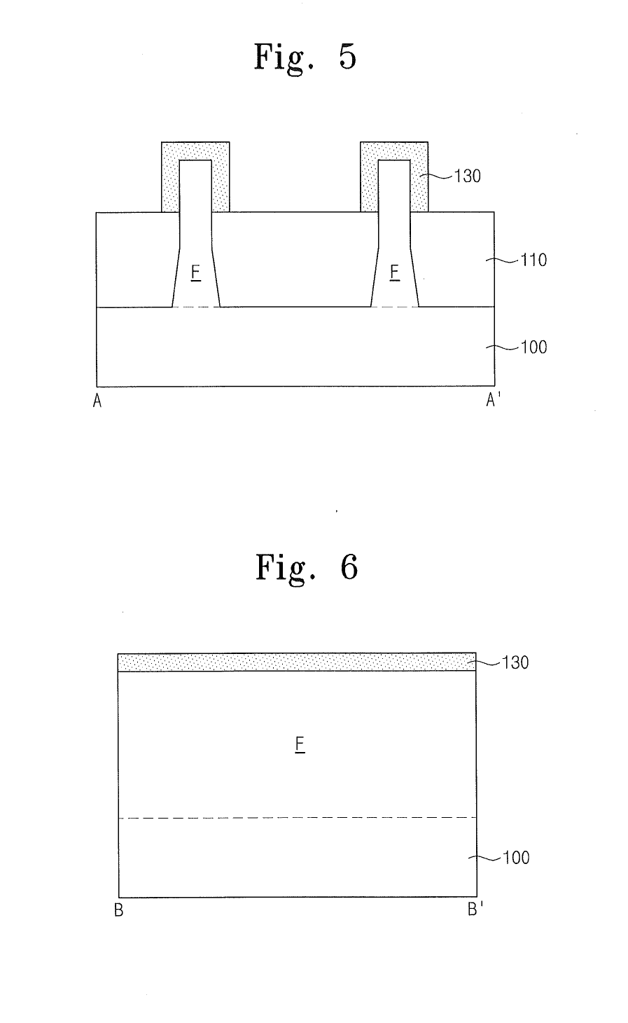

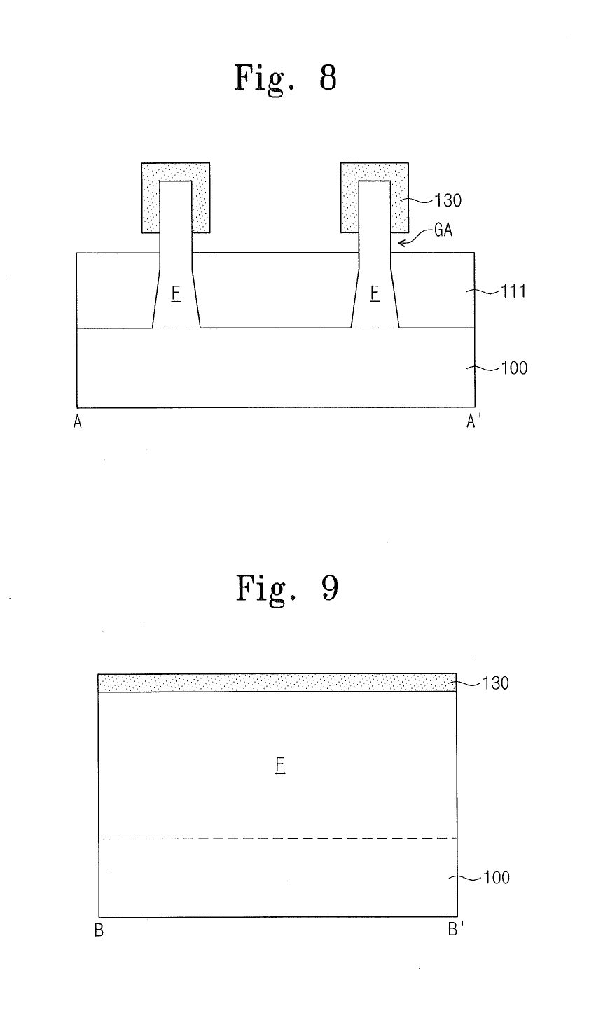

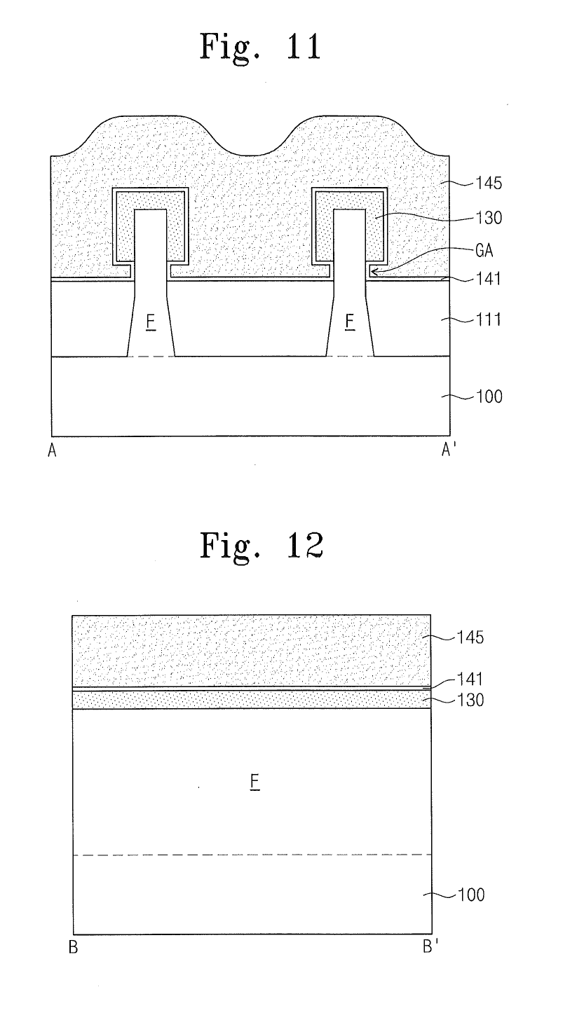

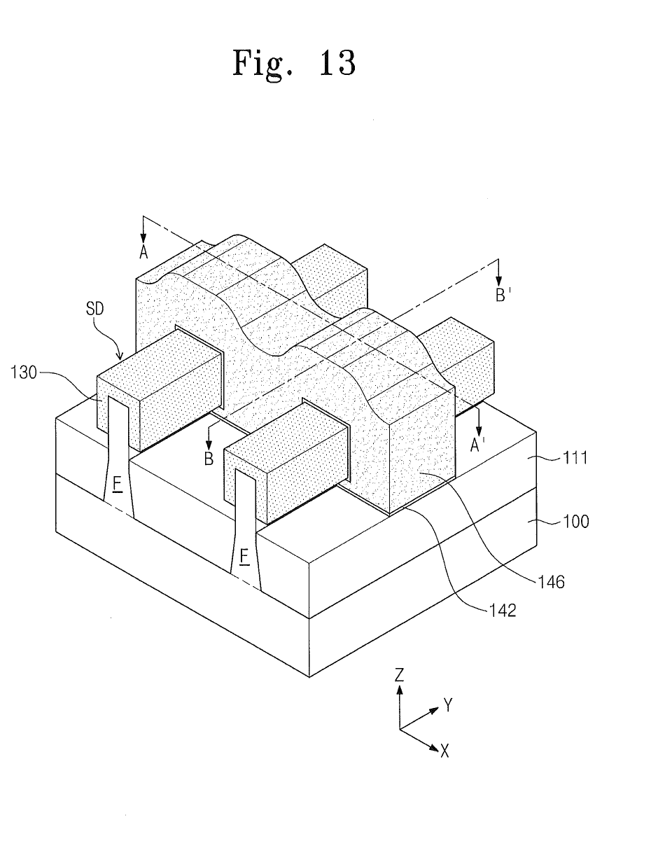

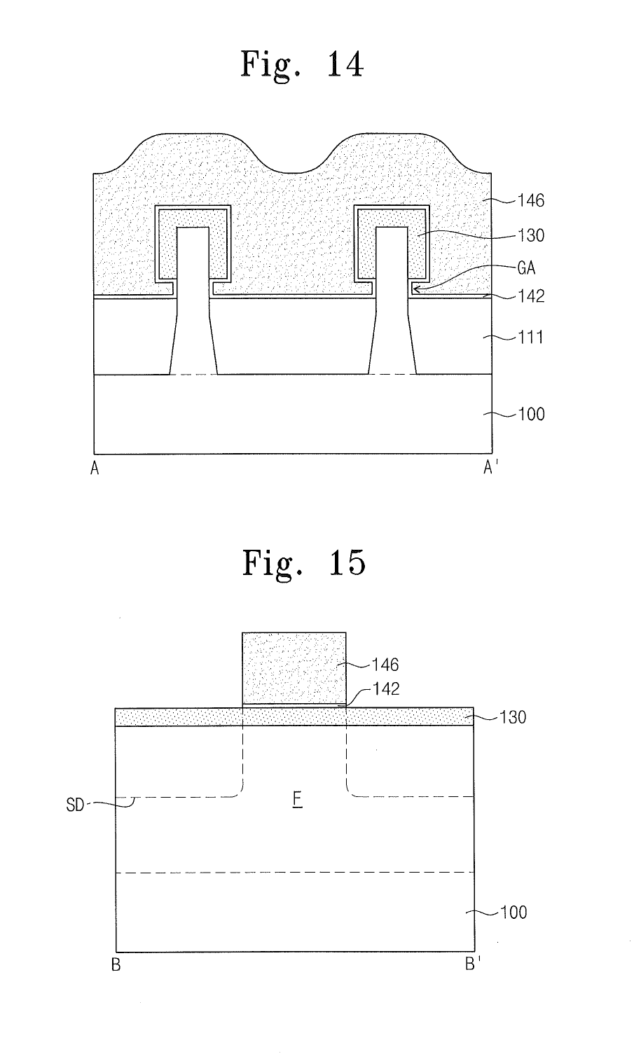

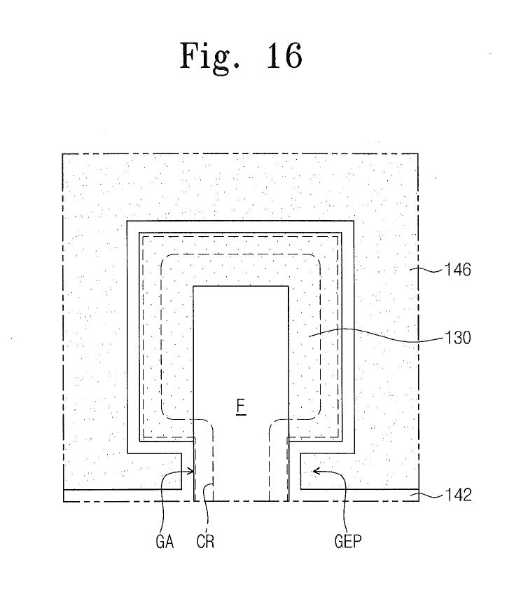

Hereinafter, a method of fabricating a field effect transistor according to example embodiments of the inventive concepts will be described with reference to FIGS. 1 through 16. In detail, FIGS. 1, 4, 7, 10, and 13 are perspective views illustrating a method of fabricating a field effect transistor according to example embodiments of the inventive concepts, FIGS. 2, 5, 8, 11, and 14 are sectional views taken along line A-A′ of FIGS. 1, 4, 7, 10, and 13, respectively, and FIGS. 3, 6, 9, 12, and 15 are sectional views taken along line B-B′ of FIGS. 1, 4, 7, 10, and 13, respectively. FIG. 16 is an enlarged view illustrating a fin portion and a region adjacent thereto of FIG. 14.

Referring to FIGS. 1 through 3, fin portions F may be formed to protrude from a substrate 100. The substrate 100 may include a single element and/or compound semiconductor based structure. For example, the substrate 100 may be a silicon substrate or a silicon-on-insulator (SOI) wafer. Each of the fin portions F may have a Y-directional length greater than an X-directional length (for example, be shaped like a line pattern whose longitudinal axis is parallel to the Y-direction). In example embodiments, the formation of the fin portions F may include forming a mask pattern (not shown) on the substrate 100 and then forming trenches 101 in the substrate 100 using the mask pattern as an etch mask. In other example embodiments, in the case where the substrate 100 includes first and second semiconductor layers and a dielectric layer therebetween (i.e., an SOI wafer), the fin portions F may be formed by patterning the second semiconductor layer provided on the dielectric layer.

Device isolation layers 110 may be formed to fill the trenches 101. The device isolation layers 110 may be a high density plasma oxide layer, a spin-on-glass (SOG) layer, and/or a CVD oxide layer. The device isolation layers 110 may be formed in the trenches 101 on, and in some embodiments to cover, lower sidewalls of the fin portions F. For example, the formation of the device isolation layers 110 may include forming an insulating layer to fill the trenches 101 and etching an upper portion of the insulating layer to expose upper portions of the fin portions. In other example embodiments, the formation of the fin portions F may include forming a mask pattern on the substrate 100, and then, performing an epitaxial process using portions of the substrate 100 exposed by the mask pattern as a seed layer. In this case, the fin portions F may be formed of the same material as the substrate 100 or a material having different lattice constant and/or bandgap from the substrate 100. For example, the substrate 100 may be a single crystalline silicon wafer, and the fin portions F may include a layer of Ge, SiGe, or SiC.

A doping process may be performed to inject dopants into the fin portions F (or control a threshold voltage of transistors). For example, in the case where the fin field effect transistor is an NMOS transistor, the dopants may include boron (B). Alternatively, in the case where the fin field effect transistor is a PMOS transistor, the dopants may include phosphorus (P) and/or arsenic (As). The doping process may be performed before and/or after the formation of the device isolation layers 110. In example embodiments, a pair of the fin portions F shown in FIG. 1 may be used to form a pair of NMOS or PMOS transistors adjacent to each other. Alternatively, one of the fin portions F may be used to form a NMOS transistor, while the other for a PMOS transistor. In this sense, a structure of a gate electrode pattern to be described below may be modified; for example, the pair of the transistors may be controlled by two gate electrode patterns separated from each other.

Referring to FIGS. 4 through 6, semiconductor layers 130 may be formed on, and in some embodiments to cover, a top surface and an upper sidewall of the fin portions F exposed by the device isolation layers 110. The semiconductor layers 130 may be formed by an epitaxial process using the fin portions F as a seed layer. For example, the semiconductor layers 130 may be formed by, for example, a molecular beam epitaxy (MBE), a liquid phase epitaxy (LPE), a vapor phase epitaxy (VPE), or an or metal-organic chemical vapor deposition (MOCVD). The semiconductor layers 130 may be locally formed on the fin portions F, respectively. In other words, the semiconductor layers 130 may be spaced apart from each other in the X direction and extend along the fin portions F or the Y direction.

In example embodiments, the semiconductor layers 130 may be formed of the same material as the fin portions F. For example, the semiconductor layers 130 and the fin portions F may be formed of silicon. In other example embodiments, the semiconductor pattern 130 may be formed of a different semiconductor material from the fin portion F. For example, in the case where the fin portion F is formed of silicon, the semiconductor pattern 130 may include InSb, InAs, GaSb, InP, GaAs, Ge, SiGe, and/or SiC. The semiconductor pattern 130 may include a semiconductor material having a different bandgap from the fin portion F. For example, the fin portion F may include a layer of GaAs, while the semiconductor pattern 130 may include a layer of AlGaAs. The semiconductor pattern 130 may be doped to have the same conductivity type as the fin portions F. For example, the semiconductor layers 130 may be doped in an in-situ manner during the epitaxial process. In example embodiments, the semiconductor layers 130 may have a doping concentration lower than that of the fin portions F.

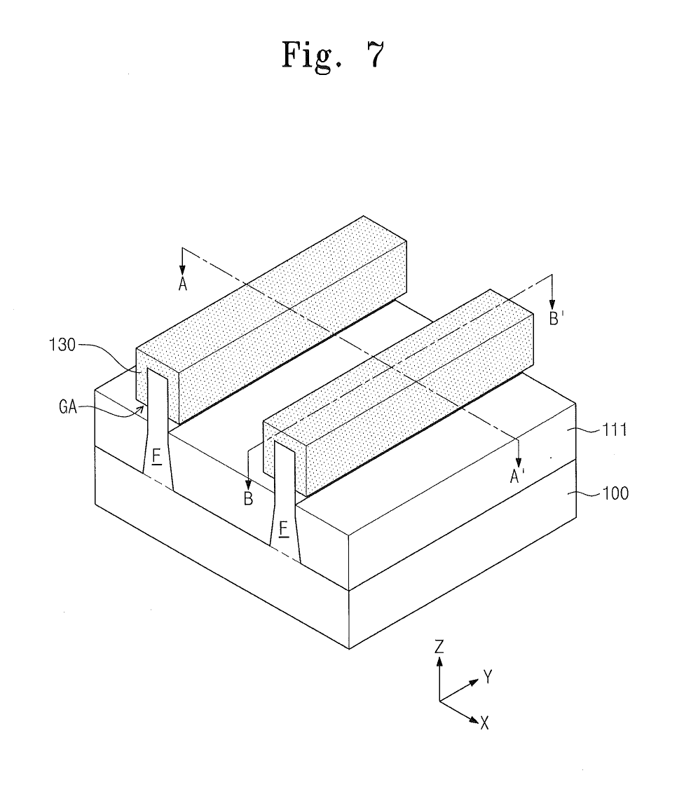

Referring to FIGS. 7 through 9, upper surfaces of the device isolation layers 110 may be selectively etched to form device isolation patterns 111. As the result of the selective etching process, gap regions GA may be formed between top surfaces of the device isolation patterns 111 and bottom surfaces of the semiconductor layers 130. The gap regions GA may extend along a extending direction of the fin portions F. The gap regions GA may be formed to at least partially expose sidewalls of the fin portions F. Each of the gap regions GA may have a boundary delimited by the bottom surface of the semiconductor layer 130, the top surface of the device isolation pattern 111, and the exposed sidewall of the fin portion F. The formation of the gap regions GA may be performed using an etchant capable of selectively etching the device isolation layers 110 (i.e., reducing or suppressing the semiconductor layers 130 from being etched). For example, in the case where the device isolation layers 110 are formed of oxide, the formation of the gap regions GA may include a wet etching process, in which a solution containing hydrofluoric acid (HF) may be used.

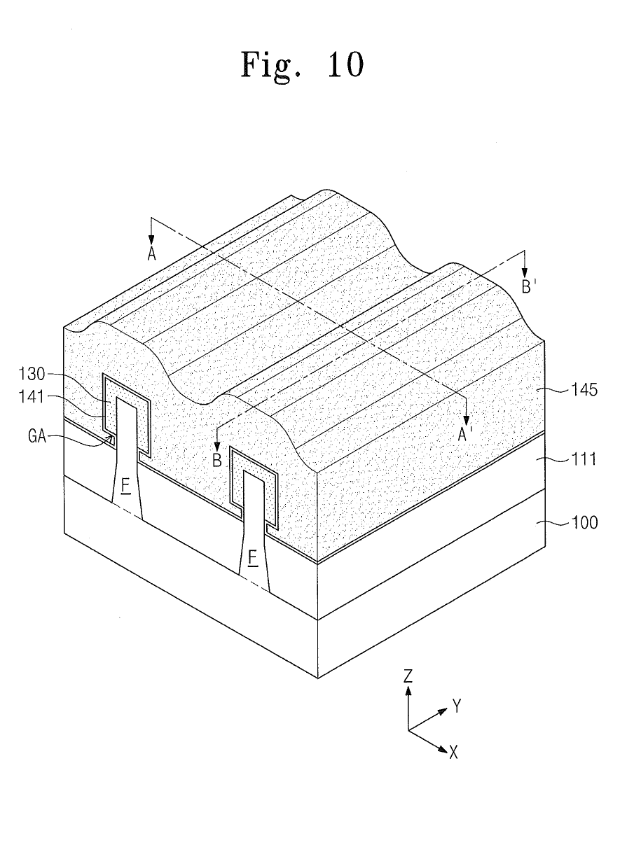

Referring to FIGS. 10 through 12, a gate dielectric 141 and a gate electrode layer 145 may be sequentially formed on the resultant structure provided with the gap regions GA. The gate dielectric 141 may be formed conformally on, and in some embodiments to conformally cover, inner surfaces of the gap regions GA (for example, the bottom surfaces of the semiconductor layers 130, the top surfaces of the device isolation patterns 111, and the exposed sidewalls of the fin portions F). The gate electrode layer 145 may fill the gap regions GA provided with the gate dielectric 141. For example, the gate electrode layer 145 may include portions interposed between the bottom surfaces of the semiconductor layers 130 and the top surfaces of the device isolation patterns 111.

The gate dielectric 141 may include an oxide layer and/or an oxynitride layer. For example, the gate dielectric 141 may be a silicon oxide layer. In example embodiments, the gate dielectric 141 may include a high-k dielectric whose dielectric constant is higher than that of the silicon oxide layer. The gate electrode layer 145 may include doped semiconductor materials, metals, conductive metal nitrides, and/or metal-semiconductor compounds. In example embodiments, at least one of the gate dielectric 141 and the gate electrode layer 145 may be formed by a chemical vapor deposition, a sputter technique, and/or an atomic layer deposition.

Referring to FIGS. 13 through 16, the gate dielectric 141 and the gate electrode layer 145 may be patterned to form a gate dielectric pattern 142 and a gate electrode pattern 146, respectively. The gate dielectric pattern 142 and the gate electrode pattern 146 may extend along the X direction (i.e., to cross the fin portions F). The patterning process may include forming a mask pattern (not shown) on the gate electrode layer 145 and etching the gate dielectric 141 and the gate electrode layer 145 using the mask pattern as an etch mask. In example embodiments, the gate dielectric 141 and the gate electrode layer 145 may be independently patterned by at least two different etching steps.

Even after the etching process, the semiconductor layers 130 and the fin portions F including portions exposed by the gate electrode pattern 146 may not be substantially etched to remain on the substrate 100. Source/drain regions SD may be formed in portions of the semiconductor layers 130 and the fin portions F exposed by the gate electrode pattern 146. For example, the source/drain regions SD may be formed by a doping process, in which the mask (not shown) used to form the gate electrode pattern 146 may be used as an ion implanting mask. In other example embodiments, portions of the semiconductor layers 130 and the fin portions F, which are not covered with the gate electrode pattern 146, may be removed during the etching process, and the source/drain regions may be formed by an additional process for forming semiconductor patterns.

Due to the presence of the gap region GA, the gate electrode pattern 146 may include portions extending below the semiconductor layer 130, as shown in FIG. 16. For example, the gate electrode pattern 146 may include gate extended portions GEP located between the semiconductor layer 130 and the device isolation patterns 111. Due to the presence of the gate extended portion GEP, it is possible to increase a width of a channel region CR. In other words, the presence of the gate extended portion GEP allows improved controllability on the channel region CR by the gate electrode pattern 146, during an operation of the field effect transistor. Furthermore, this can reduce or eliminate short channel effects including drain-induced-barrier-lowering (DIBL) phenomena. According to example embodiments of the inventive concepts, the gap regions GA for forming the gate extended portions GEP can be formed by a selective etching process.

In the conventional art, a fin field effect transistor may have a relatively narrow body region compared with the planar-type transistor. This narrow body region may lead to deterioration in charge mobility. By contrast, according to example embodiments of the inventive concepts, as the result of the formation of the semiconductor layers 130, the body region of the field effect transistor may have a width equivalent to twice the thickness of the semiconductor layer 130. As a result, it is possible to reduce or suppress the deterioration in charge mobility and the short channel effects from occurring.

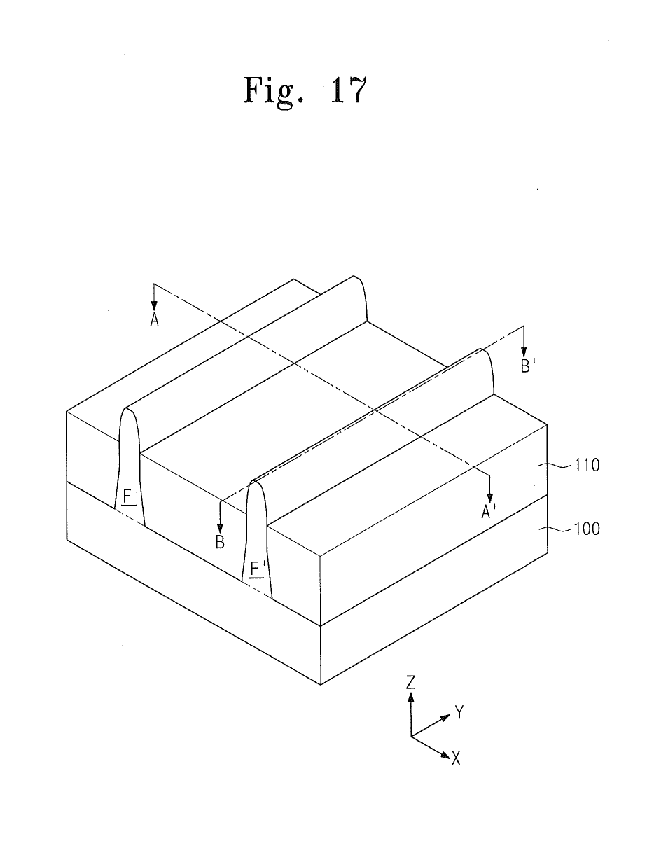

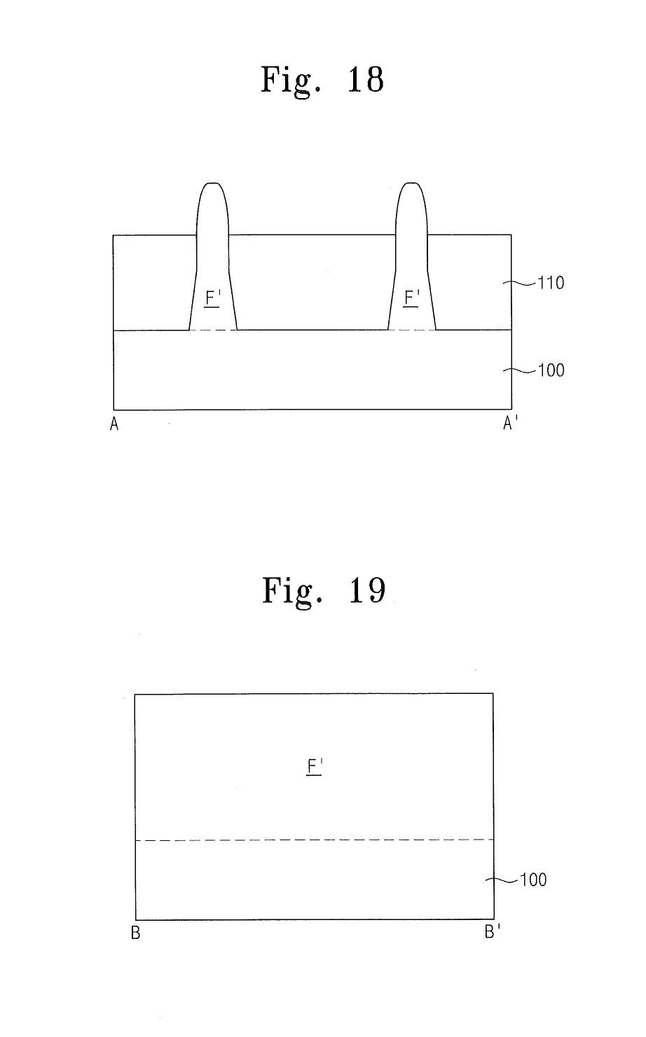

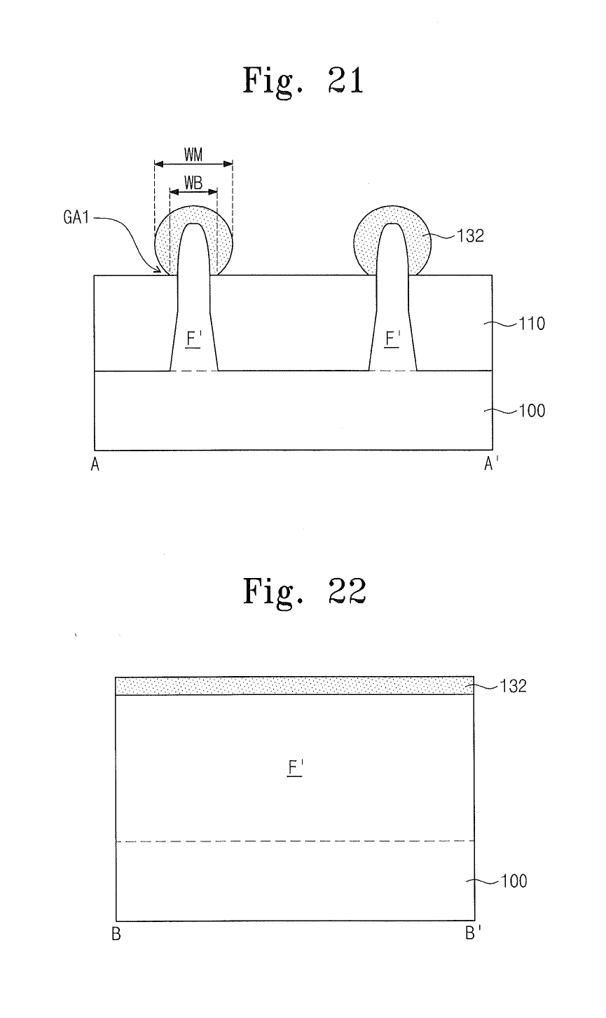

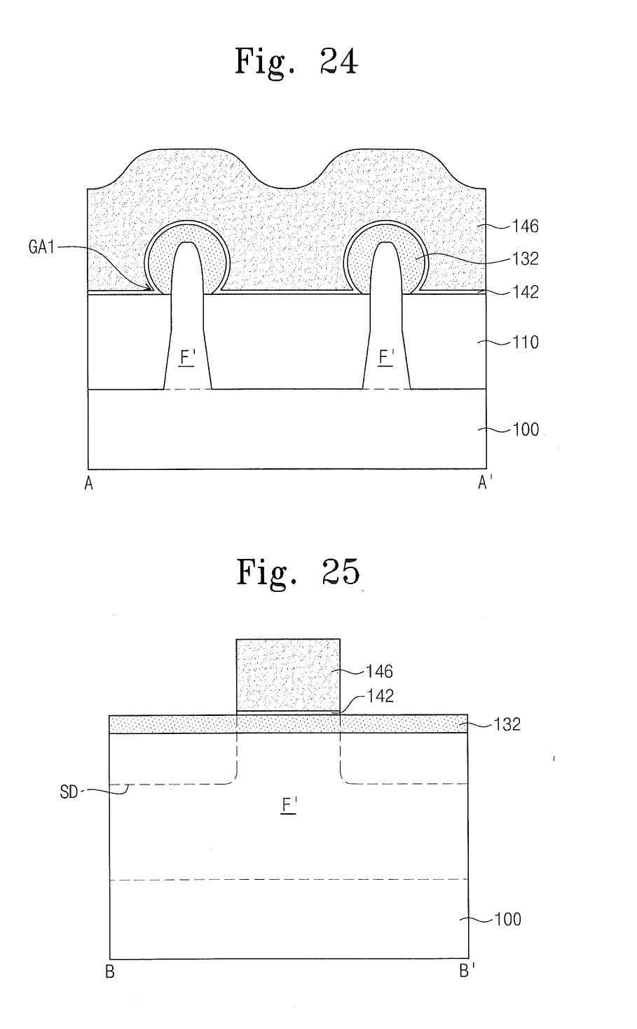

Hereinafter, a method of fabricating a field effect transistor according to other example embodiments of the inventive concepts will be described with reference to FIGS. 17 through 25. FIGS. 17, 20, and 23 are perspective views illustrating a method of fabricating a field effect transistor according to other example embodiments of the inventive concepts, FIGS. 18, 21, and 24 are sectional views taken along line A-A′ of FIGS. 17, 20, and 23, respectively, and FIGS. 19, 22, and 25 are sectional views taken along line B-B′ of FIGS. 17, 20, and 23, respectively. For convenience in description, the aforesaid technical features may be omitted below.

Referring to FIGS. 17 through 19, the fin portions F described with reference to FIG. 1 may be etched to include rounded upper portions. The etching process may be performed in dry and/or wet etching manner. An etch amount of the fin portion F in the etching process may be relatively greater in an edge thereof than other portions thereof, and thus, fin portions F′ may be formed to have rounded edge portions. The etching process may be performed using an etchant having etch selectivity with respect to the rounded fin portions F′. Alternatively, upper portions of the device isolation layers 110 may be etched during etching the upper portions of the fin portions F. In other example embodiments, during the formation of the trenches 101 of FIG. 1, the upper portions of the fin portions F may be etched to have a rounded profile.

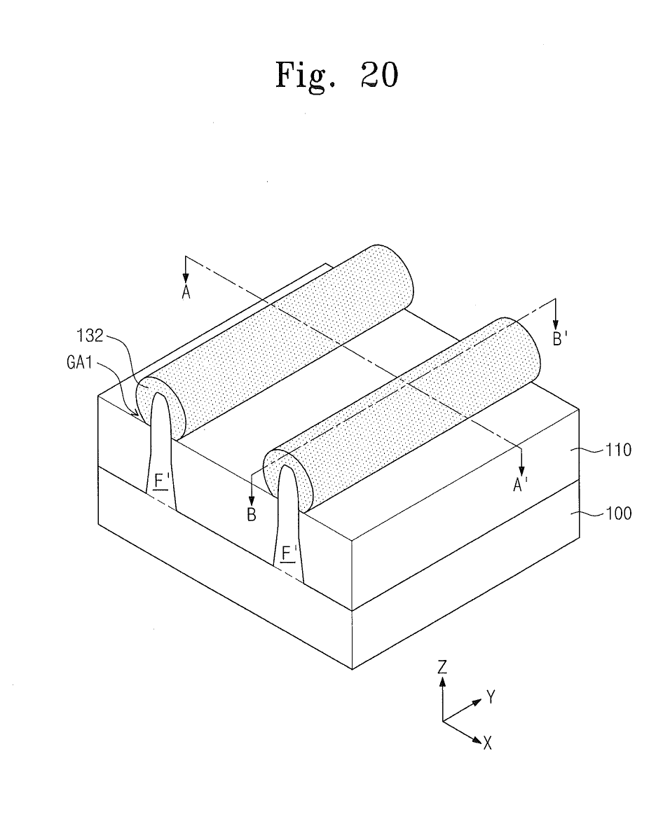

Referring to FIGS. 20 through 22, semiconductor layers 132 may be formed by an epitaxial process using the rounded fin portions F′ as a seed layer. The semiconductor layers 132 may be spaced apart from each other in the X direction and extend along the rounded fin portions F′ or the Y direction. Due to the rounded profile of the rounded fin portions F′, the semiconductor layers 132 may be formed to have a circular or elliptical (generally referred to as “rounded”) section. The semiconductor layer 132 may be formed to have a maximum width WM at its intermediate level; for example, a bottom portion of the semiconductor layer 132 may have a width WB smaller than the maximum width WM. Here, the widths WM and WB are dimensions measured along the X direction, and the maximum width WM and the bottom width WB may be regarded to include a width of the rounded fin portion F′ covered with the semiconductor layers 132. Since a bottom portion of the semiconductor layer 132 may be in contact with the device isolation layer 110, the semiconductor layer 132 may be grown most slowly at the bottom portion thereof. This is the reason for the circular or elliptical profile of the semiconductor layer 132. As a result, first gap regions GA1 may be formed between outer surfaces of the semiconductor layers 132 and top surfaces of the device isolation layers 110. Each of the first gap regions GA1 may be an empty region, which may be delimited by a slanted sidewall of the semiconductor layer 132 and the top surface of the device isolation layer 110.

The semiconductor layers 132 may be formed of the same material as the rounded fin portions F′. In example embodiments, the semiconductor layers 132 and the rounded fin portions F′ may be formed of silicon. In other embodiments, the semiconductor layers 132 may be formed of a different semiconductor material from the rounded fin portion F′.

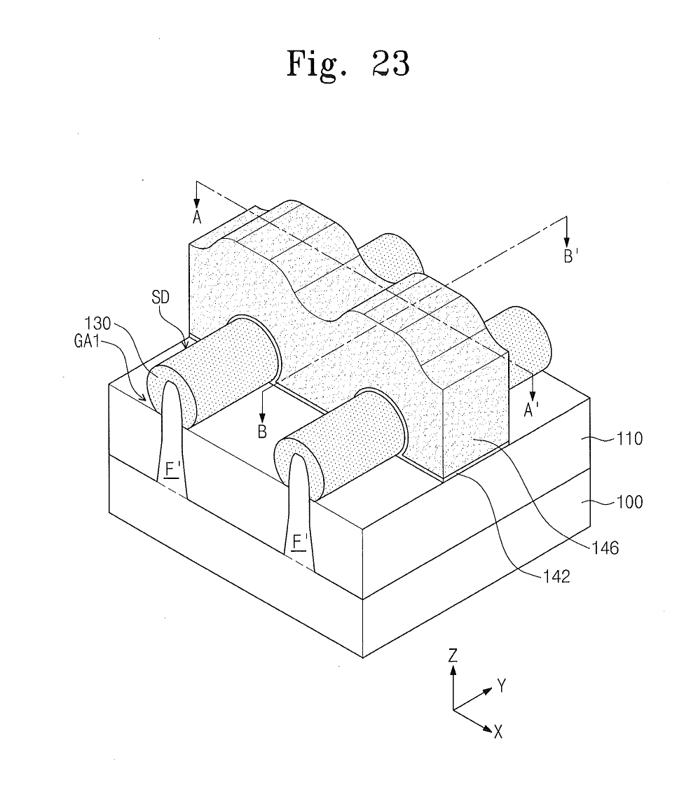

Referring to FIGS. 23 through 25, the gate dielectric pattern 142 and the gate electrode pattern 146 may be formed on the structure provided with the semiconductor layers 132. The gate dielectric pattern 142 and the gate electrode pattern 146 may be formed by the same methods as that previously described with reference to FIGS. 10 through 15. The source/drain regions SD may be formed in the semiconductor layers 132 and the rounded fin portions F′ exposed by the gate electrode pattern 146. The gate dielectric pattern 142 may be formed to conformally cover inner surfaces of the first gap regions GA1 (for example, exposed surfaces of the semiconductor layers 132 and the device isolation layers 110). The gate electrode pattern 146 may be formed to fill the first gap regions GA1 provided with the gate dielectric pattern 142. Due to the presence of the first gap regions GA1, the gate electrode pattern 146 may include portions extending below the semiconductor layer 132. As a result, it is possible to improve controllability on a channel region of a transistor by the gate electrode pattern 146 and to reduce or relieve short channel effects including drain-induced-barrier-lowering (DIBL) phenomena. According to example embodiments of the inventive concepts, the first gap regions GA1 allowing to achieve these technical effects can be formed.

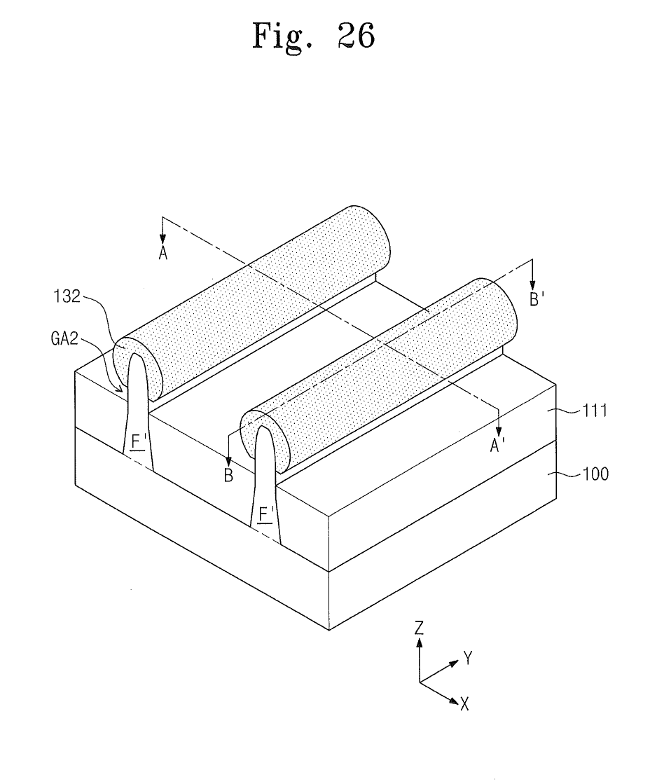

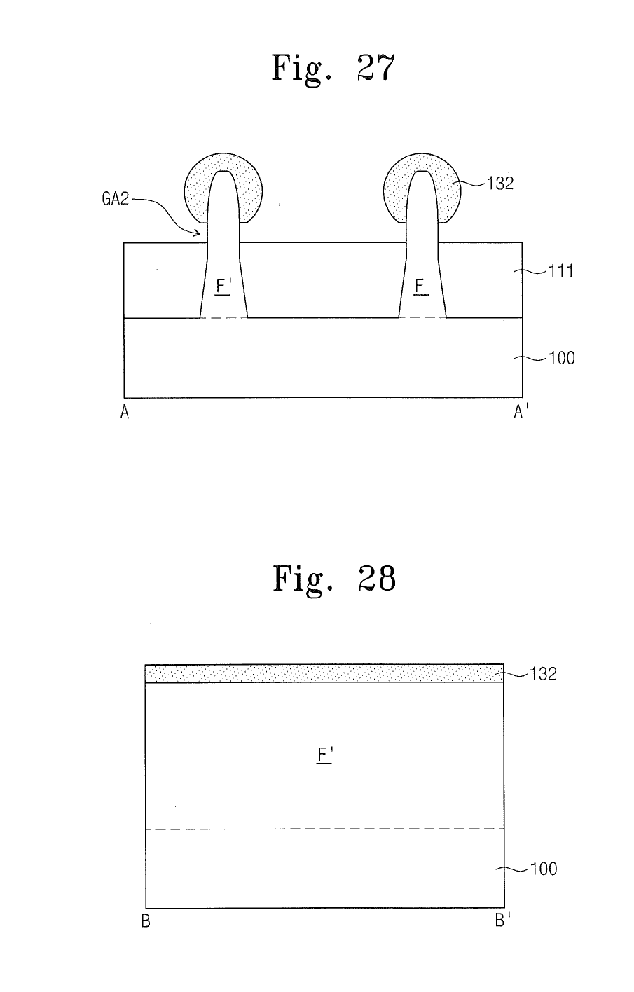

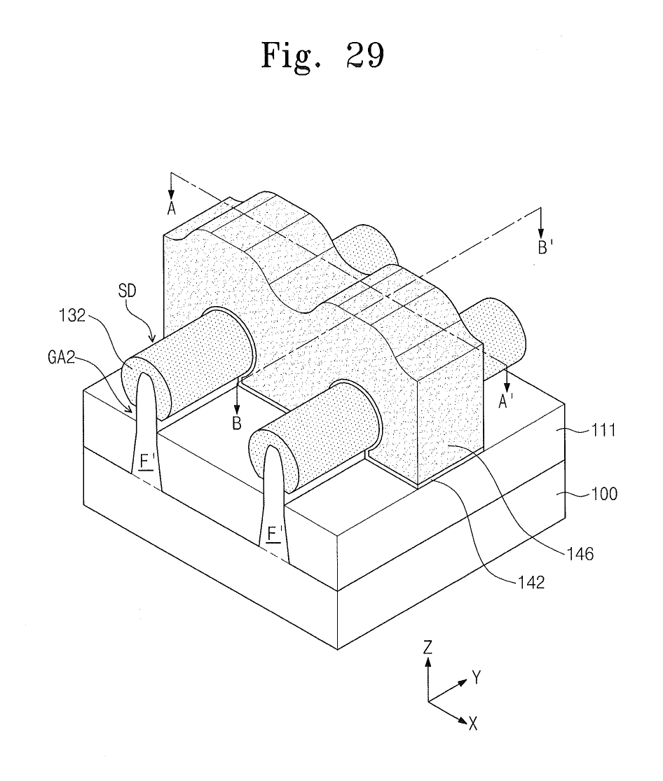

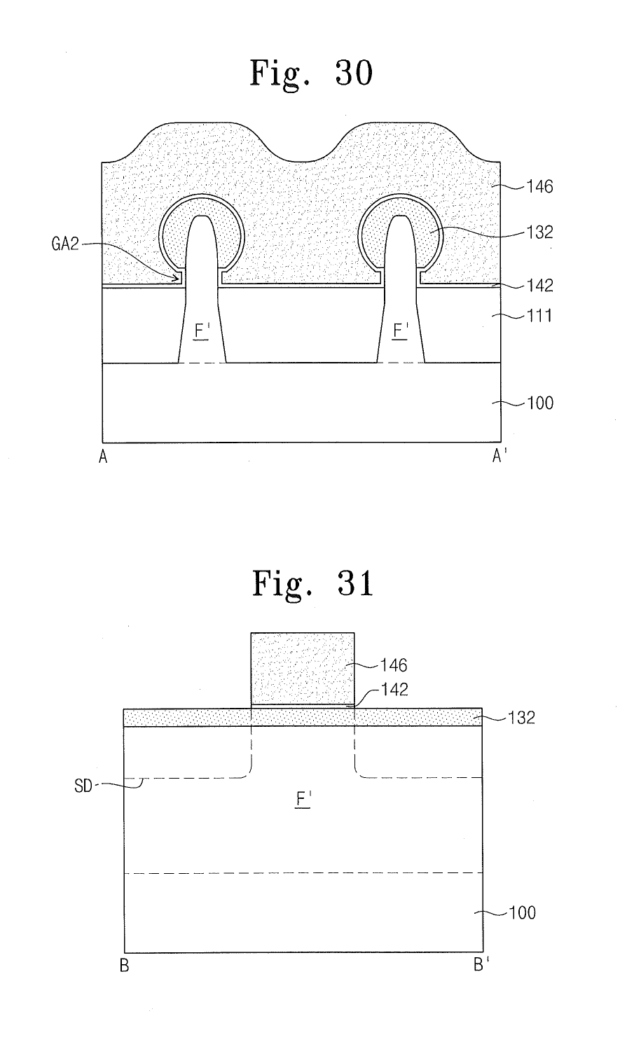

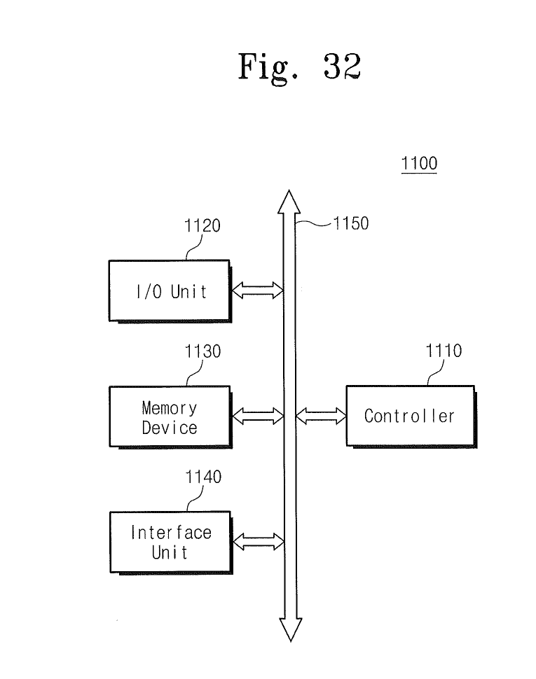

Hereinafter, a method of fabricating a field effect transistor according to still other example embodiments of the inventive concepts will be described with reference to FIGS. 26 through 31. FIGS. 26 and 29 are perspective views illustrating a method of fabricating a field effect transistor according to still other example embodiments of the inventive concepts, FIGS. 27 and 30 are sectional views taken along line A-A′ of FIGS. 26 and 29, respectively, and FIGS. 28 and 31 are sectional views taken along line B-B′ of FIGS. 26 and 29, respectively. For convenience in description, the aforesaid technical features may be omitted below.

Referring to FIGS. 26 through 28, after the formation of the semiconductor layers 132 described with reference to FIG. 20, the upper portions of the device isolation layers 110 may be selectively etched to form the device isolation patterns 111. As the result of the selective etching process, the first gap regions GA1 of FIG. 20 may be extended between the bottom surfaces of the semiconductor layers 132 and the top surfaces of the device isolation patterns 111, thereby forming second gap regions GA2. The second gap regions GA2 may be formed to at least partially expose sidewalls of the rounded fin portions F′. The formation of the second gap regions GA may be performed using an etchant capable of selectively etching the device isolation layers 110 (i.e., reducing or suppressing the semiconductor layers 132 from being etched). For example, in the case where the device isolation layers 110 are formed of oxide, the formation of the second gap regions GA2 may include a wet etching process, in which a solution containing hydrofluoric acid (HF) may be used.

Referring to FIGS. 29 through 31, the gate dielectric pattern 142 and the gate electrode pattern 146 may be formed on the structure provided with the semiconductor layers 132. The gate dielectric pattern 142 and the gate electrode pattern 146 may be formed by the same methods as that previously described with reference to FIGS. 10 through 15. The source/drain regions SD may be formed in the semiconductor layers 132 and the rounded fin portions F′ exposed by the gate electrode pattern 146. The gate dielectric pattern 142 may be formed conformally on, and in some embodiments to conformally cover, inner surfaces of the second gap regions GA2 (for example, exposed surfaces of the semiconductor layers 132, the rounded fin portions F′, and the device isolation patterns 111). The gate electrode pattern 146 may be formed in, and in some embodiments to fill, the second gap regions GA2 provided with the gate dielectric pattern 142. Due to the presence of the second gap regions GA2, the gate electrode pattern 146 may include portions extending below the semiconductor layers 146. As a result, it is possible to improve controllability on a channel region of a transistor by the gate electrode pattern 146 and to reduce or relieve short channel effects including drain-induced-barrier-lowering (DIBL) phenomena. According to example embodiments of the inventive concepts, the second gap regions GA2 allowing to achieve the technical effects can be formed.

FIG. 32 is a block diagram of an electronic system including a fin field effect transistor according to example embodiments of the inventive concepts.

Referring to FIG. 32, an electronic system 1100 according to example embodiments of the inventive concepts may include a controller 1110, an input/output (I/O) unit 1120, a memory device 1130, an interface unit 1140 and a data bus 1150. At least two of the controller 1110, the I/O unit 1120, the memory device 1130 and the interface unit 1140 may communicate with each other through the data bus 1150. The data bus 1150 may correspond to a path through which electrical signals are transmitted.

The controller 1110 may include a microprocessor, a digital signal processor, a microcontroller and/or another logic device. The other logic device may have a similar function to the microprocessor, the digital signal processor and/or the microcontroller. The I/O unit 1120 may include a keypad, a keyboard and/or a display unit. The memory device 1130 may store data and/or commands. The memory device 1130 may further include another type of data storing devices, which are different from the data storing devices described above. The interface unit 1140 may transmit electrical data to a communication network and/or may receive electrical data from a communication network. The interface unit 1140 may operate by wireless and/or cable. For example, the interface unit 1140 may include an antenna for wireless communication and/or a transceiver for cable communication. Although not shown in the drawings, the electronic system 1100 may further include a fast DRAM device and/or a fast SRAM device that acts as a cache memory for the controller 1110. The field effect transistor according to example embodiments of the inventive concepts may be provided in the memory device 1130 or serve as components of the controller 1110, the interface unit 1140 and/or the I/O unit 1120.

The electronic system 1100 may be applied to a personal digital assistant (PDA), a portable computer, a web tablet, a wireless phone, a mobile phone, a digital music player, a memory card and/or an electronic product. The electronic product may receive and/or transmit information data by wireless.

According to example embodiments of the inventive concepts, it is possible to provide methods of fabricating a fin field effect transistor, which can suppress short channel effects from occurring.

While example embodiments of the inventive concepts have been particularly shown and described, it will be understood by one of ordinary skill in the art that variations in form and detail may be made therein without departing from the spirit and scope of the attached claims.

1. A method of fabricating a field effect transistor, comprising:
forming a fin portion protruding from a substrate;
forming a device isolation layer on a lower sidewall of the fin portion;
forming a semiconductor layer using an epitaxial method on an upper sidewall and a top surface of the fin portion;
selectively etching an upper portion of the device isolation layer to form a gap region between a top surface of the device isolation layer and a bottom surface of the semiconductor layer; and
forming a gate electrode pattern on the semiconductor layer in the gap region.

2. The method of claim 1, wherein the gap region is formed to expose a portion of a sidewall of the fin portion between the top surface of the device isolation layer and the bottom surface of the semiconductor layer.

3. The method of claim 1, wherein the semiconductor layer comprises a material, whose lattice constant and/or bandgap is different from that of the fin portion.

4. The method of claim 3, wherein the semiconductor layer comprises silicon-germanium (SiGe).

5. The method of claim 1, wherein the semiconductor layer extends along a extending direction of the fin portion.

6. The method of claim 1, wherein the selectively etching of the upper portion of the device isolation layer is performed after the forming of the semiconductor layer.

7. The method of claim 1, further comprising, forming a gate dielectric between the gate electrode pattern and the semiconductor layer.

8. The method of claim 1, further comprising, etching the fin portion to have a rounded upper portion thereof, prior to the forming a semiconductor layer, so that the semiconductor layer is formed to have a rounded surface.

9.-20. (canceled)
